(19) United States
(12) Patent Application Publication
(10) Pub. No.: US 2025/0183783 A1
(43) Pub. Date: Jun. 5, 2025

(54) INVERTER AND ELECTRIC-DRIVEN VEHICLE

(71) Applicant: Mitsubishi Electric Corporation, Tokyo (JP)

(72) Inventors: Naoki YOSHIMATSU, Tokyo (JP); Shintaro ARAKI, Tokyo (JP)

(73) Assignee: Mitsubishi Electric Corporation, Tokyo (JP)

(21) Appl. No.: 18/842,382

(22) PCT Filed: Mar. 18, 2022
(86) PCT No.: PCT/JP2022/012638

§ 371 Date: Aug. 28, 2024

(51) Int. Cl. H02M 1/00; H02M 1/32; H02M 7/00; H02M 7/537; H05K 7/20

(52) U.S. Cl. CPC H02M 1/0054; H02M 1/327; H02M 7/537; H05K 7/20927; H02M 7/003

(57) ABSTRACT

This disclosure has an object of reducing the total losses of an inverter including a Si switching element and a SIC switching element that are connected in parallel. An inverter includes: a SiC MOSFET module; a Si IGBT module connected in parallel with the SiC MOSFET module; a SiC MOSFET module control circuit controlling the SiC MOSFET module; and a Si IGBT module control circuit controlling the Si IGBT module. The SiC MOSFET module control circuit terminates driving of the SiC MOSFET module when an element temperature of the SiC MOSFET module is higher than a first threshold. The Si IGBT module control circuit terminates driving of the Si IGBT module when an element temperature of the Si IGBT module is higher than a second threshold.

### TECHNICAL FIELD

The present disclosure relates to an inverter and an electric-driven vehicle.

### BACKGROUND ART

Patent Document 1 discloses a power conversion device as an inverter to be used in an electric-driven vehicle. The power conversion device includes silicon (Si) switching elements, silicon carbide (SiC) switching elements each of which is connected in parallel with a corresponding one of the Si switching elements between a power supply and a load, and a controller that selectively drives one set of the switching elements. This controller drives only the SIC switching elements at a low current. Furthermore, this controller preferentially drives the Si switching elements at a high current, and drives the SIC switching elements instead of the Si switching elements when the temperature of the Si switching elements becomes high.

### PRIOR ART DOCUMENT

### Patent Document

Patent Document 1: Japanese Patent Application Laid-Open No. 2020-092505

### SUMMARY

### Problem to be Solved by the Invention

The SIC switching elements have lower losses than the Si switching elements in a low current range, and the Si switching elements have lower losses than the SIC switching elements in a high current range. In the power conversion device in Patent Document 1, the switching elements having lower losses are selected and driven according to a current. However, selectively driving only one set of the switching elements makes it difficult to reduce the total losses.

This disclosure has been conceived to solve the problem, and has an object of reducing the total losses of an inverter including a Si switching element and a SIC switching element that are connected in parallel.

### Means to Solve the Problem

An inverter includes: a SiC MOSFET module including a plurality of SiC MOSFETs; a Si IGBT module connected in parallel with the SiC MOSFET module and including a plurality of Si IGBTs; a SiC MOSFET module control circuit controlling the SiC MOSFET module 1; and a Si IGBT module control circuit controlling the Si IGBT module. The SiC MOSFET module control circuit terminates driving of the SiC MOSFET module when an element temperature of the SiC MOSFET module is higher than a predefined first threshold. The Si IGBT module control circuit terminates driving of the Si IGBT module when an element temperature of the Si IGBT module is higher than a predefined second threshold. The SiC MOSFET module control circuit drives the SiC MOSFET module and the Si IGBT module control circuit drives the Si IGBT module, when the element temperature of the SiC MOSFET module is lower than or equal to the first threshold and the element temperature of the Si IGBT module is lower than or equal to the second threshold.

### Effects of the Invention

The total losses of an inverter according to the present disclosure are reduced. The objects, features, aspects, and advantages of the present disclosure will become more apparent from the following detailed description and the accompanying drawings.

### BRIEF DESCRIPTION OF DRAWINGS

FIG. 1 is a circuit diagram illustrating an inverter according to Embodiment 1 which is connected to a battery, a capacitor, and a motor.

FIG. 2 illustrates the current-voltage characteristics of SiC MOSFETs and Si IGBTs.

FIG. 3 illustrates the general current-voltage characteristics of the SiC MOSFETs at 25° C. and 150° C.

FIG. 4 illustrates the general current-voltage characteristics of the Si IGBTs at 25° C. and 150° C.

FIG. 5 illustrates that a SiC MOSFET module and a Si IGBT module are mounted on a cooler according to Embodiment 1.

FIG. 6 illustrates that the SiC MOSFET module and the Si IGBT module are mounted on a cooler according to Embodiment 2.

FIG. 7 illustrates that the SiC MOSFET module and the Si IGBT module are mounted on a cooler according to Embodiment 3.

### DESCRIPTION OF EMBODIMENTS

### A. Embodiment 1

### A-1. Structure

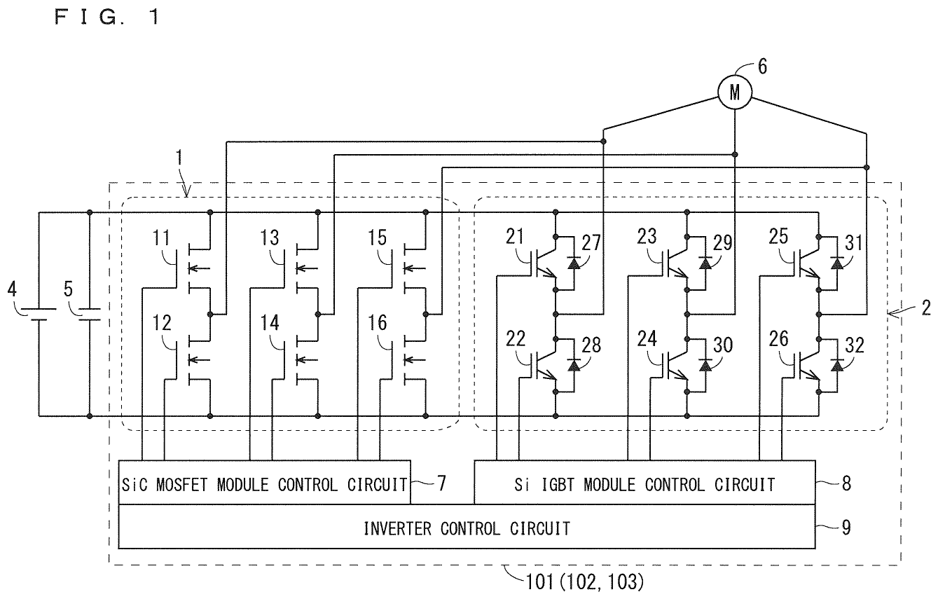

FIG. 1 is a circuit diagram illustrating an inverter 101 according to Embodiment 1 which is connected to a battery 4, a capacitor 5, and a motor 6.

The motor 6 is a motor for an electric-driven vehicle such as an electric vehicle or a hybrid vehicle.

The inverter 101 includes a SiC MOSFET module 1, a Si IGBT module 2, a SiC MOSFET module control circuit 7, a Si IGBT module control circuit 8, and an inverter control circuit 9.

The SiC MOSFET module 1 includes a plurality of SiC metal-oxide-semiconductor field-effect transistors (MOSFETs). In FIG. 1, the SiC MOSFET module 1 includes six SiC MOSFETs 11 to 16. The SiC MOSFET 11 is a U-phase upper arm. The SiC MOSFET 12 is a U-phase lower arm. The SiC MOSFET 13 is a V-phase upper arm. The SiC MOSFET 14 is a V-phase lower arm. The SiC MOSFET 15 is a W-phase upper arm. The SiC MOSFET 16 is a W-phase lower arm.

The Si IGBT module 2 includes a plurality of Si insulated gate bipolar transistors (IGBTs). In FIG. 1, the Si IGBT module 2 includes six Si IGBTs 21 to 26, and freewheeling diodes 27 to 32 that are connected in parallel with the respective Si IGBTs 21 to 26. The Si IGBT 21 is a U-phase upper arm. The Si IGBT 22 is a U-phase lower arm. The Si IGBT 23 is a V-phase upper arm. The Si IGBT 24 is a V-phase lower arm. The Si IGBT 25 is a W-phase upper arm. The Si IGBT 26 is a W-phase lower arm.

A P terminal, a N terminal, a U terminal, a V terminal, and a W terminal that are main terminals of the SiC MOSFET module 1 are connected in parallel with a P terminal, a N terminal, a U terminal, a V terminal, and a W terminal that are main terminals of the Si IGBT module 2, respectively. The U terminals, the V terminals, and the W terminals of the SiC MOSFET module 1 and the Si IGBT module 2 are connected to the motor 6, and the P terminals and the N terminals thereof are connected to the battery 4 and the capacitor 5.

The SiC MOSFET module control circuit 7 is a control circuit for the SiC MOSFET module 1. Signal terminals such as gate terminals of the SiC MOSFETs 11 to 16 in the SiC MOSFET module 1 are connected to the SiC MOSFET module control circuit 7.

The Si IGBT module control circuit 8 is a control circuit for the Si IGBT module 2. Signal terminals such as gate terminals of the Si IGBTs 21 to 26 in the Si IGBT module 2 are connected to the Si IGBT module control circuit 8.

The SiC MOSFET module control circuit 7 and the Si IGBT module control circuit 8 are connected to the inverter control circuit 9.

FIG. 1 illustrates the Si IGBTs 21 to 26, and the freewheeling diodes 27 to 32 that are connected in parallel with the respective Si IGBTs 21 to 26 as the structure of the Si IGBT module 2. The freewheeling diodes 27 to 32 may include freewheeling diode elements separate from IGBT elements included in the Si IGBTs 21 to 26. Alternatively, the Si IGBTs 21 to 26 and the freewheeling diodes 27 to 32 may include RC-IGBT elements including freewheeling diodes.

FIG. 1 illustrates only the gate terminals as the signal terminals of the SiC MOSFETs 11 to 16 and the Si IGBTs 21 to 26. Each of the SiC MOSFETs 11 to 16 and the Si IGBTs 21 to 26 may include, however, a current sense terminal, a temperature sense terminal, and a collector sense terminal. Furthermore, each of the SiC MOSFETs 11 to 16 may include a source sense terminal. Furthermore, each of the Si IGBTs 21 to 26 may include an emitter sense.

### A-2. Operations

The SiC MOSFET module control circuit 7 switches the SiC MOSFET module 1 upon receipt of a PWM signal from the inverter control circuit 9. As a result, the DC current input from the battery 4 or the capacitor 5 to the SiC MOSFET module 1 through the P terminal and the N terminal is output to the motor 6 through the U terminal, the V terminal, and the W terminal as a three-phase AC current.

Similarly, the Si IGBT module control circuit 8 switches the Si IGBT module 2 upon receipt of a PWM signal from the inverter control circuit 9. As a result, the DC current input from the battery 4 or the capacitor 5 to the Si IGBT module 2 through the P terminal and the N terminal is output to the motor 6 through the U terminal, the V terminal, and the W terminal as a three-phase AC current.

The SiC MOSFET module control circuit 7 monitors the element temperature of the SiC MOSFET module 1. When the element temperature is higher than a predefined first threshold, the SiC MOSFET module control circuit 7 blocks an input signal to the gate of the SiC MOSFET module 1. Here, only the Si IGBT module 2 drives the motor 6. The SiC MOSFET module control circuit 7 simultaneously outputs, to the inverter control circuit 9, a signal indicating that the element temperature of the SiC MOSFET module 1 is higher than the first threshold. Upon receipt of the signal indicating that the element temperature of the SiC MOSFET module 1 is higher than the first threshold, the inverter control circuit 9 outputs, to the Si IGBT module control circuit 8, a signal indicating that output of the Si IGBT module 2 is to be suppressed. Then, the Si IGBT module control circuit 8 suppresses the output of the Si IGBT module 2. This suppresses an increase in the temperature of the Si IGBT module 2 driven alone.

Similarly, the Si IGBT module control circuit 8 also monitors the element temperature of the Si IGBT module 2. When the element temperature is higher than a predefined second threshold, the Si IGBT module control circuit 8 blocks an input signal to the gate of the Si IGBT module 2. Here, only the SiC MOSFET module 1 drives the motor 6. The Si IGBT module control circuit 8 simultaneously outputs, to the inverter control circuit 9, a signal indicating that the element temperature of the Si IGBT module 2 is higher than the second threshold. Upon receipt of the signal indicating that the element temperature of the Si IGBT module 2 is higher than the second threshold, the inverter control circuit 9 outputs, to the SiC MOSFET module control circuit 7, a signal indicating that output of the SiC MOSFET module 1 is to be suppressed. Then, the SiC MOSFET module control circuit 7 suppresses the output of the SiC MOSFET module 1. This suppresses an increase in the temperature of the Si IGBT module 2 driven alone.

When the element temperature of the SiC MOSFET module 1 is lower than or equal to the first threshold and the element temperature of the Si IGBT module 2 is lower than or equal to the second threshold, both of the SiC MOSFET module 1 and the Si IGBT module 2 are driven.

The SiC MOSFET module 1 and the Si IGBT module 2 differ in cooling condition, thermal condition, and heat resistance performance. Thus, the SiC MOSFET module 1 and the Si IGBT module 2 differ in threshold of the element temperature at which the input signal is blocked.

The heat generated in the SiC MOSFETs 11 to 16 and the Si IGBTs 21 to 26 is dissipated through die bonded joints on which these elements are mounted. The die bonded joints are prone to cracks due to heating and cooling cycles generated by turning ON and OFF the elements. Normally, the cracks worsen thermal dissipation, and the temperature of the elements easily rises, which contribute to the progress of cracks. In the inverter 101 according to Embodiment 1, however, the SiC MOSFET module control circuit 7 and the Si IGBT module control circuit 8 monitor the element temperatures of the SiC MOSFETs 11 to 16 and the Si IGBTs 21 to 26 and terminates driving of these elements when the element temperatures reach the respective thresholds. Thus, the progress of cracks in the die bonded joints can be delayed.

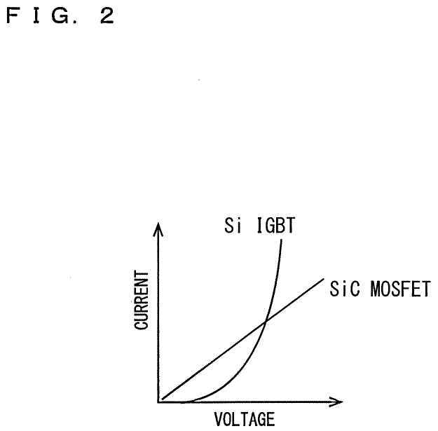

FIG. 2 illustrates the current-voltage characteristics of SiC MOSFETs and Si IGBTs. Causing currents to flow through the SiC MOSFETs and the Si IGBTs generates losses from resistance components of these elements. The SiC MOSFETs and the Si IGBTs have, however, different characteristics to the currents as illustrated in FIG. 2. Specifically, the SiC MOSFETs have lower voltages, that is, lower resistances in a low current range, and the Si IGBTs have lower voltages, that is, lower resistance in a high current range. When the SiC MOSFETs are connected in parallel with the Si IGBTs, much current flows through a low resistance side.

Patent Document 1 proposes selectively driving the SiC MOSFETs in a low current range and selectively driving the Si IGBTs in a high current range, using these characteristics. However, driving both of the SiC MOSFETs and the Si IGBTs reduces the total losses in any of a low current range and a high current range.

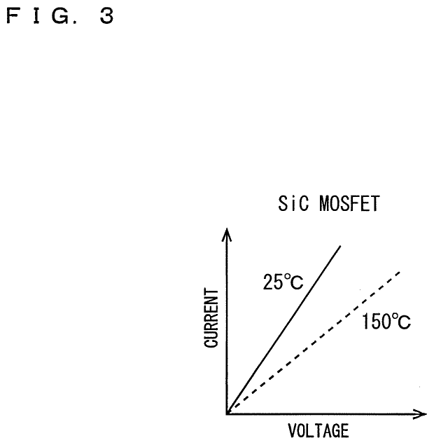

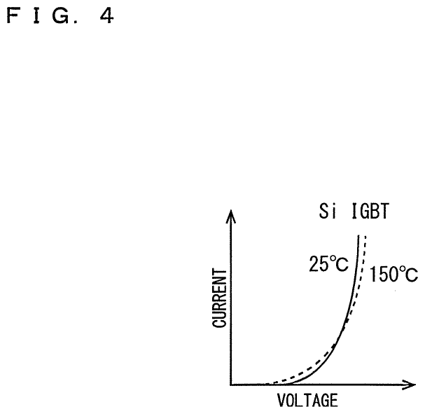

FIG. 3 illustrates the general current-voltage characteristics of the SiC MOSFETs at 25° C. and 150° C. FIG. 4 illustrates the general current-voltage characteristics of the Si IGBTs at 25° C. and 150° C.

As illustrated in FIG. 3, the voltage of the SiC MOSFETs at the high temperature rises more extremely than that at the low temperature. As illustrated in FIG. 4, the Si IGBTs at the high temperature have lower voltages in a low current range, and conversely, the Si IGBTs at the low temperature have lower voltages in a high current range. However, the difference in voltage between the high temperature and the low temperature is not as large as that of the SiC MOSFETs. Since each of the elements generates heat due to a resistance component when energized, a cooler needs to cool the modules more efficiently.

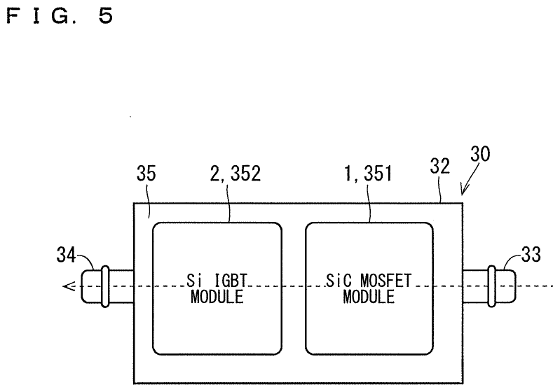

FIG. 5 illustrates that the SiC MOSFET module 1 and the Si IGBT module 2 are mounted on a cooler 30. In other words, the inverter 101 according to Embodiment 1 includes the cooler 30.

The cooler 30 includes a housing 32, an inlet water pipe 33, and an outlet water pipe 34. The housing 32 includes a top plate 35 on which the SiC MOSFET module 1 and the Si IGBT module 2 are mounted. A region of the top plate 35 on which the SiC MOSFET module 1 is mounted will be referred to as a first region 351, and a region of the top plate 35 on which the Si IGBT module 2 is mounted will be referred to as a second region 352. A coolant supplied from the inlet water pipe 33 to the housing 32 cools the SiC MOSFET module 1 and the Si IGBT module 2 while flowing through the housing 32, and exits from the outlet water pipe 34. Thus, the housing 32 has a flow channel of the coolant indicated by a dotted-line arrow in FIG. 5.

As illustrated in FIG. 5, the SiC MOSFET module 1 is mounted more upstream than the Si IGBT module 2 in the flow channel of the coolant. In other words, the first region 351 is located more upstream than the second region 352 in the flow channel of the coolant.

With such a structure, the coolant supplied from the inlet water pipe 33 to the housing 32 first cools the SiC MOSFET module 1 and then cools the Si IGBT module 2, and exits from the outlet water pipe 34. Since the coolant flows through the cooler 30 while removing heat from each of the modules, the SiC MOSFET module 1 located upstream is cooled with higher cooling performance than that of the Si IGBT module 2 located downstream.

As illustrated in FIGS. 3 and 4, a heating value of the SiC MOSFETs is higher than that of the Si IGBTs at the high temperature. Thus, disposing the SiC MOSFET module 1 in a position of the cooler 30 with higher cooling performance than that of the Si IGBT module 2 can suppress the total losses in the inverter 101.

### A-3. Advantages

The inverter 101 according to Embodiment 1 includes the SiC MOSFET module 1 including the plurality of SiC MOSFETs 11 to 16, the Si IGBT module 2 connected in parallel with the SiC MOSFET module 1 and including the Si IGBTs 21 to 26, the SiC MOSFET module control circuit 7 controlling the SiC MOSFET module 1, and the Si IGBT module control circuit 8 controlling the Si IGBT module 2. The SiC MOSFET module control circuit 7 terminates driving of the SiC MOSFET module 1 when an element temperature of the SiC MOSFET module 1 is higher than a predefined first threshold. The Si IGBT module control circuit 8 terminates driving of the Si IGBT module 2 when an element temperature of the Si IGBT module 2 is higher than a predefined second threshold. The SiC MOSFET module control circuit 7 drives the SiC MOSFET module 1 and the Si IGBT module control circuit 8 drives the Si IGBT module 2, when the element temperature of the SiC MOSFET module 1 is lower than or equal to the first threshold and the element temperature of the Si IGBT module 2 is lower than or equal to the second threshold.

In the aforementioned structure, both the SiC MOSFET module 1 and the Si IGBT module 2 drive the motor 6 when the element temperatures are not high. Thus, the structure can suppress the total losses in the inverter 101 more than that when only one of the modules drives the motor 6.

In the case where the element temperature of the SiC MOSFET module 1 is higher than the first threshold, the Si IGBT module control circuit 8 reduces output of the Si IGBT module 2 more than output when the element temperature of the SiC MOSFET module 1 is lower than or equal to the first threshold, and in the case where the element temperature of the Si IGBT module 2 is higher than the second threshold, the SiC MOSFET module control circuit 7 reduces output of the SiC MOSFET module 1 more than output when the element temperature of the Si IGBT module 2 is lower than or equal to the second threshold. This can prevent the switching elements in the SiC MOSFET module 1 or the Si IGBT module 2 which operates alone from being destroyed.

The inverter according to Embodiment 1, further including the cooler 30 on which the SiC MOSFET module 1 and the Si IGBT module 2 are mounted, wherein cooling performance of the cooler 30 at a position on which the SiC MOSFET module 1 is mounted is higher than cooling performance of the cooler 30 at a position on which the Si IGBT module 2 is mounted. This allows the SiC MOSFET module 1 with a higher heating value at a high temperature to be more preferentially cooled than the Si IGBT module 2, which can suppress the total losses in the inverter 101.

The cooler 30 includes: the housing 32; the inlet water pipe 33 supplying a coolant into the housing 32; and the outlet water pipe 34 discharging the coolant from the housing 32. The housing 32 includes the first region 351 on which the SiC MOSFET module 1 is mounted, and the second region 352 on which the Si IGBT module 2 is mounted. The first region 351 is located more upstream than the second region 352, in a flow channel of the coolant from the inlet water pipe 33 to the outlet water pipe 34. Thus, the coolant supplied from the inlet water pipe 33 to the cooler 3 dissipates heat from the SiC MOSFET module 1 earlier than the Si IGBT module 2. This allows the SiC MOSFETs with higher heating values at a high temperature to be more preferentially cooled than the Si IGBTs, which can suppress the total losses in the inverter 101.

### B. Embodiment 2

### B-1. Structure

The circuit structure of an inverter 102 according to Embodiment 2 is the one illustrated in FIG. 1, and is identical to that of the inverter 101 according to Embodiment 1. The inverter 102 includes a cooler 30A, instead of the cooler 30 in the inverter 101 according to Embodiment 1.

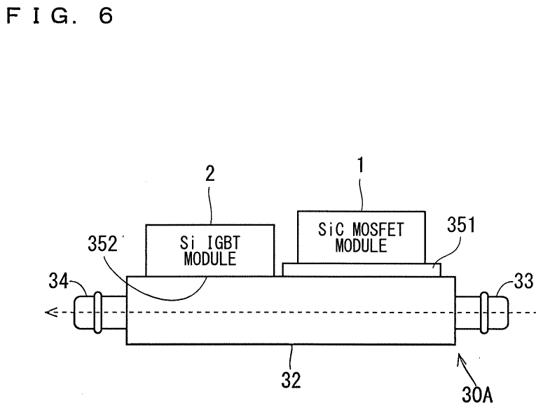

FIG. 6 illustrates that the SiC MOSFET module 1 and the Si IGBT module 2 are mounted on the top plate 35 of the cooler 30A. Disposing the SiC MOSFET module 1 more upstream than the Si IGBT module 2 in the flow channel of the coolant is identical to that in Embodiment 1.

The first region 351 is thicker than the second region 352 in the top plate 35 of the cooler 30A. In other words, the first region 351 has larger heat capacity and has higher cooling performance than those of the second region 352. The structure of the cooler 30A other than the thicknesses of the top plate 35 is identical to that of the cooler 30 according to Embodiment 1.

The load of an electric-driven vehicle including the inverter 102 temporarily increases upon sudden acceleration such as overtaking. Here, a high current flows through the SiC MOSFET module 1 with a small resistance value, which instantaneously increases the heating value. In the inverter 102, however, the heat in the SiC MOSFET module 1 can be dissipated not only to the coolant of the cooler 30A but also to the first region 351 of the top plate 35 having high heat capacity. Thus, rise in the element temperature in the SiC MOSFET module 1 can be suppressed.

### B-2. Advantages

The housing 32 of the cooler 30A in the inverter 102 according to Embodiment 2 includes the first region 351 on which the SiC MOSFET module 1 is mounted, and the second region 352 on which the Si IGBT module 2 is mounted. The first region 351 is thicker than the second region 352. This increases the cooling performance of the SiC MOSFET module 1 with a higher heating value at a high temperature. Thus, the total losses in the inverter 102 can be suppressed.

### C. Embodiment 3

### C-1. Structure

The circuit structure of an inverter 103 according to Embodiment 3 is the one illustrated in FIG. 1, and is identical to that of the inverter 101 according to Embodiment 1. The inverter 103 includes a cooler 30B, instead of the cooler 30 in the inverter 101 according to Embodiment 1.

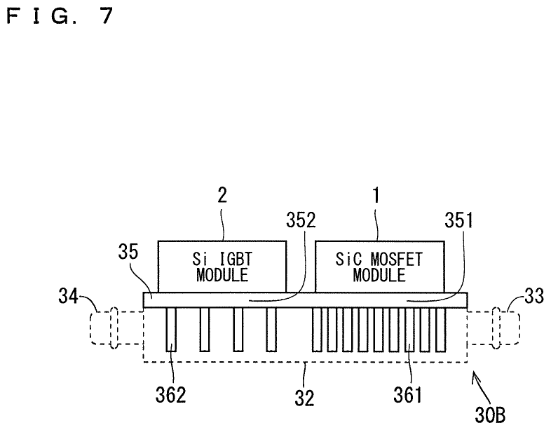

FIG. 7 illustrates that the SiC MOSFET module 1 and the Si IGBT module 2 are mounted on the top plate 35 of the cooler 30B. FIG. 7 illustrates, with dotted lines, an outer frame portion except the top plate 35 of the cooler 30B to visualize internal fins of the cooler 30B. Disposing the SiC MOSFET module 1 more upstream than the Si IGBT module 2 in the flow channel of the coolant is identical to that in Embodiment 1.

The cooler 30B differs from the cooler 30 according to Embodiment 1 by including a plurality of first fins 361 protruding from the first region 351 of the top plate 35 into the cooler 30B, and a plurality of second fins 362 protruding from the second region 352 of the top plate 35 into the cooler 30B. The first fins 361 and the second fins 362, which are pin fins in FIG. 7, may be fins of another shape.

The cooling capacity and the hydraulic resistance of fins of a cooler vary according to the shape of the fins. The fins densely disposed increases a contact area between the fins and a coolant, which increases thermal exchange efficiency. On the contrary, the fins densely disposed increases the hydraulic resistance, and reduces the velocity of the coolant.

In this respect, the plurality of first fins 361 are disposed in series with the plurality of second fins 362 in the flow channel of the coolant from the inlet water pipe 33 to the outlet water pipe 34, in the cooler 30B according to Embodiment 3. A density of the plurality of first fins 361 disposed in the first region 351 is higher than that of the plurality of second fins 362 disposed in the second region 352. In other words, the plurality of first fins 361 are densely disposed, and the plurality of second fins 362 are sparsely disposed.

This structure can suppress an increase in the hydraulic resistance more than a structure in which all fins are densely disposed, and cool the SiC MOSFET module 1 efficiently.

### C-2. Advantages

The housing 32 of the cooler 30B in the inverter 103 according to Embodiment 3 includes the first region 351 on which the SiC MOSFET module 1 is mounted, and the second region 352 on which the Si IGBT module 2 is mounted. The cooler 30B includes: the plurality of first fins 361 protruding from the first region 351 into the flow channel of the coolant; and the plurality of second fins 362 protruding from the second region 352 into the flow channel of the coolant. A density of the plurality of first fins 361 disposed in the first region 351 is higher than a density of the plurality of second fins 362 disposed in the second region 352. The aforementioned structure suppresses an increase in the hydraulic resistance in the cooler 30, and increases the cooling performance in the first region 351. Consequently, the SiC MOSFET module 1 with a high heating value at a high temperature can be cooled efficiently. This can suppress the total losses in the inverter 103.

Embodiments can be freely combined, and appropriately modified or omitted. The aforementioned description is in all aspects illustrative. Therefore, numerous modifications and variations that have not yet been exemplified can be devised.

### EXPLANATION OF REFERENCE SIGNS

1 SiC MOSFET module, 2 Si IGBT module, 4 battery, 5 capacitor, 6 motor, 7 SiC MOSFET module control circuit, 8 Si IGBT module control circuit, 9 inverter control circuit, 27 to 32 freewheeling diode, 30, 30A, 30B cooler, 32 housing, 33 inlet water pipe, 34 outlet water pipe, 35 top plate, 101, 102, 103 inverter, 351 first region, 352 second region, 361 first fin, 362 second fin.

1. An inverter, comprising:
a SiC MOSFET module including a plurality of SiC MOSFETS;
a Si IGBT module connected in parallel with the SiC MOSFET module and including a plurality of Si IGBTs;
a SiC MOSFET module control circuit controlling the SiC MOSFET module; and
a Si IGBT module control circuit controlling the Si IGBT module,
wherein the SiC MOSFET module control circuit terminates driving of the SiC MOSFET module when an element temperature of the SiC MOSFET module is higher than a predefined first threshold,
the Si IGBT module control circuit terminates driving of the Si IGBT module when an element temperature of the Si IGBT module is higher than a predefined second threshold, and
the SiC MOSFET module control circuit drives the SiC MOSFET module and the Si IGBT module control circuit drives the Si IGBT module, when the element temperature of the SiC MOSFET module is lower than or equal to the first threshold and the element temperature of the Si IGBT module is lower than or equal to the second threshold.

2. The inverter according to claim 1,
wherein in the case where the element temperature of the SiC MOSFET module is higher than the first threshold, the Si IGBT module control circuit reduces output of the Si IGBT module more than output when the element temperature of the SiC MOSFET module is lower than or equal to the first threshold, and
in the case where the element temperature of the Si IGBT module is higher than the second threshold, the SiC MOSFET module control circuit reduces output of the SiC MOSFET module more than output when the element temperature of the Si IGBT module is lower than or equal to the second threshold.

3. The inverter according to claim 1, further comprising
a cooler on which the SiC MOSFET module and the Si IGBT module are mounted,
wherein cooling performance of the cooler at a position on which the SiC MOSFET module is mounted is higher than cooling performance of the cooler at a position on which the Si IGBT module is mounted.

4. The inverter according to claim 3,
wherein the cooler includes:
a housing;
an inlet water pipe supplying a coolant into the housing; and
an outlet water pipe discharging the coolant from the housing,
the housing includes a first region on which the SiC MOSFET module is mounted, and a second region on which the Si IGBT module is mounted, and
the first region is located more upstream than the second region, in a flow channel of the coolant from the inlet water pipe to the outlet water pipe.

5. The inverter according to claim 4,
wherein the first region is thicker than the second region.

6. The inverter according to claim 4,
wherein the cooler includes:
a plurality of first fins protruding from the first region into the flow channel of the coolant; and
a plurality of second fins protruding from the second region into the flow channel of the coolant, and
a density of the plurality of first fins disposed in the first region is higher than a density of the plurality of second fins disposed in the second region.

7. An electric-driven vehicle, comprising:
the inverter according to claim 1; and
a motor to be driven by the inverter.
